(19) United States
(12) Patent Application Publication
(10) Pub. No.: US 2025/0258110 A1
(43) Pub. Date: Aug. 14, 2025

(54) DEVICE FOR DETECTING SAR, METHOD FOR REDUCING SAR, AND MOBILE TERMINAL

(71) Applicant: ZTE CORPORATION, Shenzhen (CN)

(72) Inventor: Ruibin LIU, Shenzhen (CN)

(21) Appl. No.: 19/196,589

(22) Filed: May 1, 2025

Related U.S. Application Data
(63) Continuation of application No. 17/624,230, filed on Dec. 30, 2021, now Pat. No. 12,320,760.

(30) Foreign Application Priority Data
Jul. 12, 2019 (CN) 201910630690.1

(51) Int. Cl. G01N 22/00; G01D 5/24

(52) U.S. Cl. CPC G01N 22/00; G01D 5/24

(57) ABSTRACT

The present application relates to a device and a method for detecting SAR and a mobile terminal. The device includes: an SAR sensor, a plurality of first capacitance limitation modules, a plurality of second capacitance limitation modules, and a plurality of signal isolation modules. The SAR sensor includes a plurality of detection ports and each detection port is configured to perform SAR detection on one antenna. The first end and second end of each first capacitance limitation module are connected to the antenna and the detection port respectively. The first end and second end of each second capacitance limitation module is connected to the detection port and a power control circuit respectively. The first end of each signal isolation module is connected to the antenna; the second end of each signal isolation module is connected to the detection port.

### CROSS REFERENCE TO RELATED APPLICATIONS

This application is a continuation of U.S. application Ser. No. 17/624,230 filed on Dec. 30, 2021, which is the U.S. National Phase Application under 35 U.S.C. § 371 of International Application No. PCT/CN2020/093857 filed on Jun. 2, 2020, which claims priority to Chinese patent application NO. 201910630690.1 filed on Jul. 12, 2019, the disclosures of all of which are incorporated herein by reference in their entireties.

### TECHNICAL FIELD

The present disclosure relates to the field of antenna technology, in particular, to a device for detecting SAR, a method for reducing SAR, and a mobile terminal.

### BACKGROUND

2G, 3G, and 4G networks coexist currently after years of development of mobile terminals. With the development of the 5th-generation (5G) communication technology, the number of antennas will further increase, and the problem of specific absorption rate (SAR) will increase.

Take mobile phone as an example of the mobile terminals discussed herein, while development of the 5G communication is accelerating, there are more and more antennas in a mobile phone that operate simultaneously for emitting electromagnetic energy, such as main antenna, WiFi antenna, and multiple-input multiple-output (MIMO) antenna. Consequently, tissues and organs of the human body are exposed more to electromagnetic radiation.

### SUMMARY

The present disclosure provides a device for detecting specific absorption rate (SAR), a method for reducing SAR, and a mobile terminal. Herein, detection on SARs of multiple antennas in the mobile terminal may be performed through an SAR sensor.

An embodiment of the present disclosure provides a device for detecting SAR including: an SAR sensor 1, a plurality of first capacitance limitation modules 2, a plurality of second capacitance limitation modules 3, and a plurality of signal isolation modules 4.

The SAR sensor 1 includes a plurality of detection ports 11, and each of the detection ports 11 is configured to perform SAR detection on one of antennas 5.

A first end of each of the first capacitance limitation modules 2 is connected to one of the antennas 5, a second end of each of the first capacitance limitation modules 2 is connected to one of the detection ports 11, and the first capacitance limitation modules 2 are configured to limit a capacitance value on an antenna 5 side.

A first end of each of the second capacitance limitation modules 3 is connected to one of the detection ports 11, a second end of each of the second capacitance limitation modules 3 is connected to one of power control circuits 6, and the second capacitance limitation module 3 is configured to limit a capacitance value on a power control circuit 6 side.

A first end of each of the signal isolation modules 4 is connected to one of the antennas 5, a second end of each of the signal isolation modules 4 is connected to one of the detection ports 11, and each of the signal isolation module 4 is configured to isolate radio frequency signals on a radio frequency path between the one of antennas 5 and the power control circuit 6 and to transmit SAR signals of the antenna 5.

An embodiment of the present disclosure further provides a method for reducing specific absorption rate SAR, including separately obtaining SAR signals of a plurality of antennas through a plurality of detection channels of an SAR sensor; determining the closeness of a human body to an antenna corresponding to a detection channel according to an SAR signal obtained by each detection channel; and reducing a transmission power of the antenna in a case where the closeness of the human body to the antenna is less than or equal to a safe distance.

An embodiment of the present disclosure further provides a mobile terminal including the device for detecting SAR as described above.

### BRIEF DESCRIPTION OF THE DRAWINGS

FIG. 1 is a schematic diagram showing a device for detecting SAR according to Embodiment One.

FIG. 2 is a schematic diagram showing a radio frequency path including a radio frequency cable according to Embodiment One.

FIG. 3 is a schematic diagram showing a first capacitance limitation module according to Embodiment One.

FIG. 4 is a schematic diagram showing a second capacitance limitation module according to Embodiment One.

FIG. 5 is a schematic diagram showing a signal isolation module according to Embodiment One.

FIG. 6 is a flow chart showing a method for reducing SAR according to Embodiment Two.

FIG. 7 is a schematic diagram showing an apparatus for reducing SAR on a mobile terminal according to Embodiment One.

### REFERENCE SIGNS

1—SAR sensor;
2—first capacitance limitation module;
3—second capacitance limitation module;
4—signal isolation module;
5—antenna;
6—power control circuit;
7—radio frequency cable;
8—antenna matching circuit;
11—detection port of the SAR sensor;
21—first capacitance limitation module for a first antenna;
22—first capacitance limitation module for a second antenna;
31—second capacitance limitation module for the first antenna;
32—second capacitance limitation module for the second antenna;
41—signal isolation module for the first antenna;
42—signal isolation module for the second antenna;
51—first antenna;
52—second antenna;
61—first power control circuit;
62—second power control circuit;
81—first antenna matching circuit;
82—second antenna matching circuit;
101—first circuit board;
102—second circuit board;
111—first detection port of the SAR sensor;
112—second detection port of the SAR sensor.

### DETAILED DESCRIPTION

Embodiments of the present disclosure are described with reference to the drawings as follows.

In the present disclosure, a plurality of embodiments are described for illustrating rather than limiting. There may be more embodiments and solutions within a scope of the embodiments described in the present disclosure. Although some possible combinations of characteristics are shown in the drawings and discussed in the embodiments, other combinations of the characteristics disclosed herein may also be possible. Except for a case where limitation is specified, any characteristic or element of any embodiment may be combined with or replaced with any other characteristic or element in any other embodiment.

The embodiments, characteristics, and elements disclosed in the present disclosure may be combined with conventional characteristics or elements to form the solutions of the present disclosure. Any characteristic or element of any of the embodiments may be combined with a characteristic or element in another technical solution. Any feature shown and/or discussed in the present disclosure may be implemented individually or in any appropriate combination.

SAR sensors emerge for the protection of human health. An SAR sensor may automatically detect whether there is a human body approaching an antenna within a certain range of distances from the antenna. A human body is a semi-conductor. When the human body is approaching an antenna (metal), a capacitance value sensed by the antenna changes. A chip of the SAR sensor detects the closeness of the human body to the antenna by detecting capacitance changes in the antenna.

### Embodiment One

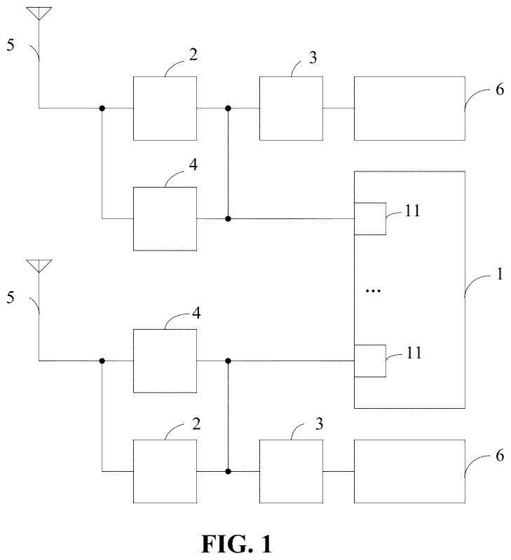

As shown in FIG. 1, an embodiment of the present disclosure provides a device for detecting a specific absorption rate SAR, including: an SAR sensor 1, a plurality of first capacitance limitation modules 2, a plurality of second capacitance limitation modules 3, and a plurality of signal isolation modules 4. Herein, the SAR sensor 1 includes a plurality of detection ports 11, and each of the detection port 11 is configured to perform SAR detection on one of the antennas 5. A first end of each of the first capacitance limitation module 2 is connected to one of the antennas 5; a second end of the first capacitance limitation module 2 is connected to one of the detection ports 11. The first capacitance limitation module 2 is configured to limit a capacitance value on an antenna 5 side. A first end of a second capacitance limitation module 3 is connected to one of the detection ports 11, a second end of the second capacitance limitation module 3 is connected to a power control circuit 6, and the second capacitance limitation module 3 is configured to limit a capacitance value on a power control circuit 6 side. A first end of each of the signal isolation modules 4 is connected to one of the antennas 5, a second end of the signal isolation module 4 is connected to one of the detection ports 11, and the signal isolation module 4 is configured to isolate radio frequency signals on a radio frequency path between the antenna 5 and the power control circuit 6 and to transmit SAR signals of the antenna 5.

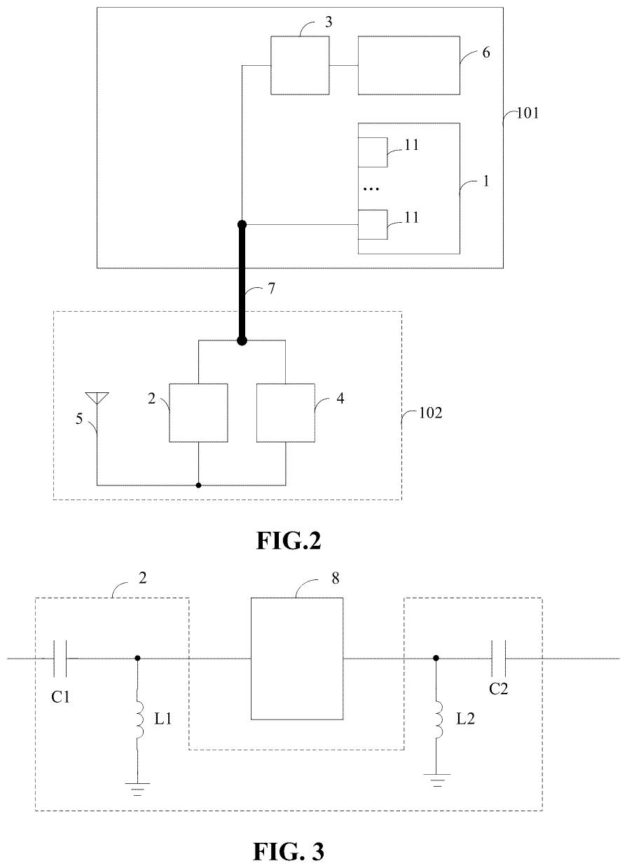

In one implementation, as shown in FIG. 2, in a case where the antenna 5 and the SAR sensor 1 are not on a same circuit board, the radio frequency path between the antenna 5 and the power control circuit 6 includes a radio frequency cable 7 connecting two circuit boards. A first end of the radio frequency cable 7 is configured to be separately connected to a second end of a first capacitance limitation module 2 and a second end of a signal isolation module 4, and a second end of the radio frequency cable 7 is configured to be connected to the detection port 11. Herein, the SAR sensor 1 and the power control circuit 6 are provided on a first circuit board 101, and the antenna 5 is provided on a second circuit board 102.

In one implementation, the first circuit board 101 is a main board, while the second circuit board 102 is a sub-board; or the first circuit board 101 is the sub-board, while the second circuit board 102 is the main board.

In the above implementation, SAR detection of an antenna not on the same circuit board as the SAR sensor may be performed by using a radio frequency cable between two circuit boards. In this way, one SAR sensor chip may synchronously perform SAR detection on multiple antennas.

In one implementation, the radio frequency path between the antenna 5 and the power control circuit 6 includes an antenna matching circuit 8, the antenna matching circuit 8 includes a resistor, a capacitor, and an inducer, and is configured to perform impedance matching on the antenna 5. There may be various forms of the antenna matching circuit 8, and the circuit is well known in the art.

As shown in FIG. 3, the radio frequency path between the antenna 5 and the power control circuit 6 includes the antenna matching circuit 8 configured to perform impedance matching on the antenna 5.

The first capacitance limitation module 2 includes: a first capacitor C1, a second capacitor C2, a first inducer L1, and a second inducer L2; a first end of the first capacitor C1 is taken as a first end of the first capacitance limitation module 2, a second end of the first capacitor C1 is connected to a first end of the first inducer L1 and a first end of the antenna matching circuit 8 respectively, and a second end of the first inducer L1 is grounded; a first end of the second capacitor C2 is separately connected to a second end of the antenna matching circuit 8 and a first end of the second inducer L2, and a second end of the second inducer L2 is grounded; and a second end of the second capacitor C2 is taken as a second end of the first capacitance limitation module 2.

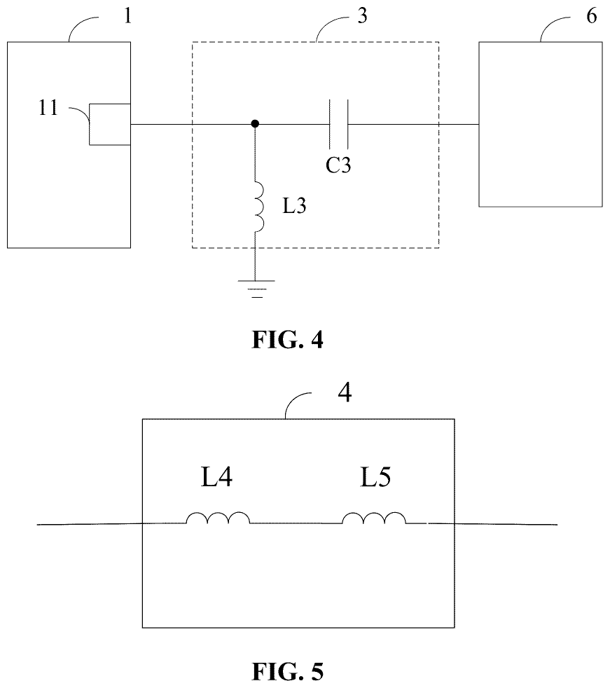

In one implementation, as shown in FIG. 4, a second capacitance limitation module 3 includes a third capacitor C3 and a third inducer L3; a first end of the third capacitor C3 is taken as a first end of the second capacitance limitation module 3, a second end of the third capacitor C3 is taken as a second end of the second capacitance limitation module 3; and a first end of the third inducer L3 is connected to the first end of the third capacitor C3, and a second end of the third inducer L3 is grounded. Herein, the first capacitance limitation module 2 may make a capacitance value detected at an antenna 5 side by the detection port 11 of the SAR sensor not change with a capacitance of the antenna matching circuit 8, thereby a big capacitance of the antenna matching circuit 8 will not affect the detection port 11 of the SAR sensor.

The second capacitance limitation module 3 may make a capacitance value detected at a power control circuit 6 side by the detection port 11 of the SAR sensor not change with a capacitance of the power control circuit 6, thereby a big capacitance of the power control circuit 6 will not affect the detection port 11 of the SAR sensor.

In one implementation, as shown in FIG. 5, the signal isolation module 4 includes an inducer L4 and an inducer L5; and a first end of the inducer L4 is taken as a first end of the signal isolation module 4, a second end of the inducer L4 is connected to a first end of the inducer L5, and a second end of the inducer L5 is taken as a second end of the signal isolation module 4. Herein, the frequency of the SAR detecting signals is low, for example, from dozens to hundreds of KHzs. However, the frequency of communication signals on a radio frequency path between an antenna and an antenna signal transceiver module is usually as much as hundreds of MHz to several GHz, and the power thereof is large. By setting the signal isolation module 4 before the detection port 11 of the SAR sensor, high-frequency communication signals on the antenna may be prevented from affecting SAR detection through blocking of inductance on the high-frequency communication signals, and SAR signals on the antenna 5 may be transmitted.

Compared with existing technologies, the device for detecting SAR according to the embodiment of the present disclosure uses multiple channels of an SAR sensor to perform SAR detection on multiple antennas and uses a signal isolation module so that the radio frequency signals between an antenna and a power control circuit will not affect a detection port of the SAR sensor and a big capacitance will not affect the SAR detection.

### Embodiment Two

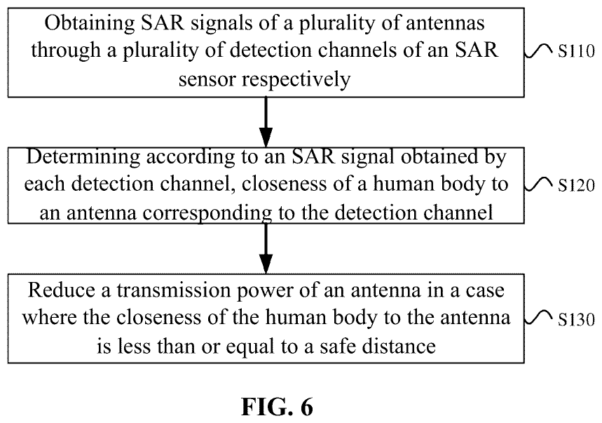

As shown in FIG. 6, an embodiment of the present disclosure provides a method for reducing a specific absorption rate SAR, including the following steps: at step S110: SAR signals of a plurality of antennas are obtained respectively through a plurality of detection channels of an SAR sensor; at step S120: closeness of a human body to an antenna corresponding to each detection channel is determined according to an SAR signal obtained through each detection channel; and at step S130: a transmission power of an antenna is reduced if the closeness of the human body to the antenna is less than or equal to a safe distance.

In the above implementations, a mobile terminal may be held by a user with various gestures. In some scenarios, one antenna in the mobile terminal may be close to the user so that the SAR is excessively high, while other antennas are distant from the user and the SARs of these antennas are not excessively high. With one SAR sensor synchronously detecting the SAR signals of multiple antennas and then processing the SAR signal of each antenna, reducing the SAR of each antenna may be independent. Therefore, the solution for reducing SAR is more flexible, and the hardware cost thereof is reduced.

### Embodiment Three

An embodiment of the present disclosure provides a mobile terminal including the device for detecting SAR according to Embodiment One.

The technical solution for detecting SAR in the present disclosure is described with the following examples.

### Example 1

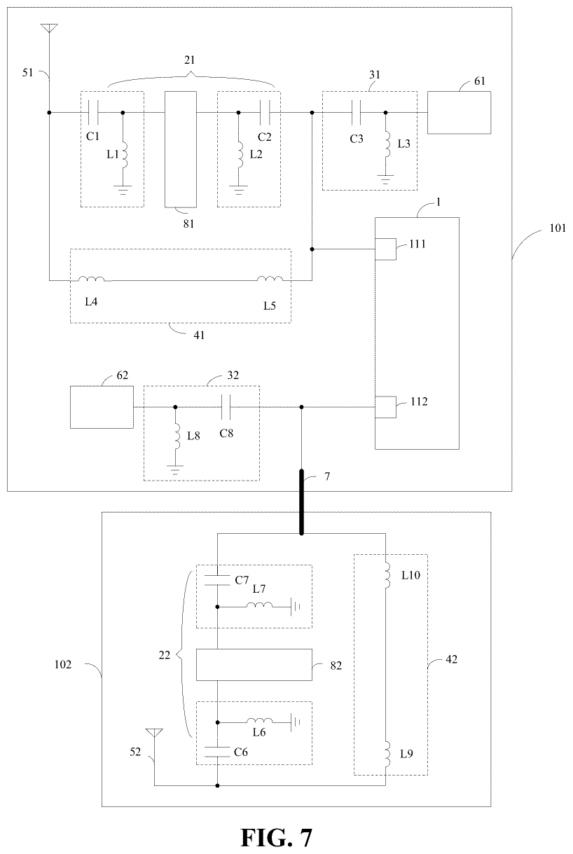

As shown in FIG. 7, this example provides a device for detecting SAR in a mobile terminal. The mobile terminal includes: a first circuit board (main board) 101; a second circuit board (sub-board) 102; a first antenna (WiFi antenna) 51, a first power control circuit 61, a second power control circuit 62, and a device for detecting SAR, provided on the main board 101; and a second antenna (main antenna) 52 provided on the sub-board 102.

The device for detecting SAR includes an SAR sensor 1, a first capacitance limitation module 21 for the first antenna, a second capacitance limitation module 31 for the first antenna, a signal isolation module 41 for the first antenna, a first capacitance limitation module 22 for the second antenna, a second capacitance limitation module 32 for the second antenna and a signal isolation module 42 for the second antenna.

The SAR sensor 1 includes a first detection port 111 and a second detection port 112. The first detection port 111 is configured to perform SAR detection on the first antenna 51, and the second detection port 112 is configured to perform SAR detection on the second antenna 52.

A radio frequency path between the first antenna 51 and the first power control circuit 61 includes a first antenna matching circuit 81. A radio frequency path between the second antenna 52 and the second power control circuit 62 includes a second antenna matching circuit 82. Each of the first antenna matching circuit 81 and the second antenna matching circuit 82 includes a resistor, a capacitor, and an inducer and is configured to perform impedance matching on the antenna. There may be various forms of the circuits which is commonly known in the art.

The first capacitance limitation module 21 for the first antenna includes a first capacitor C1, a second capacitor C2, a first inducer L1, and a second inducer L2. A first end of the first capacitor C1 is taken as a first end of the first capacitance limitation module 21 for the first antenna and is connected to the first antenna 51. A second end of the first capacitor C1 is connected to a first end of the first inducer L1 and a first end of the first antenna matching circuit 81 respectively. A second end of the first inducer L1 is grounded. A first end of the second capacitor C2 is connected to a second end of the first antenna matching circuit 81 and a first end of the second inducer L2 respectively. A second end of the second inducer L2 is grounded. A second end of the second capacitor C2 is taken as a second end of the first capacitance limitation module 21 for the first antenna and is connected to the first detection port 111.

The second capacitance limitation module 31 for the first antenna includes a third capacitor C3 and a third inducer L3. A first end of the third capacitor C3 is taken as a first end of the second capacitance limitation module 31 for the first antenna and is connected to the first detection port 111. A second end of the third capacitor C3 is taken as a second end of the second capacitance limitation module 31 for the first antenna and is connected to the first power control circuit 61. A first end of the third inducer L3 is connected to the first end of the third capacitor C3, and a second end of the third inducer L3 is grounded.

The signal isolation module 41 for the first antenna includes an inducer L4 and an inducer L5. A first end of the inducer L4 is taken as a first end of the signal isolation module 41 for the first antenna and is connected to the first antenna 51. A second end of the inducer L4 is connected to a first end of the inducer L5. A second end of the inducer L5 is taken as a second end of the signal isolation module 41 for the first antenna and is connected to the first detection port 111. The signal isolation module 41 for the first antenna is configured to isolate radio frequency signals on the radio frequency path between the first antenna 51 and the first power control circuit 61 and to transmit SAR signals of the first antenna 51.

The second antenna 52 is provided on the sub-board 102. Both the SAR sensor 1 and the second power control circuit 62 are provided on the main board 101. Therefore, the radio frequency path between the second antenna 52 and the second power control circuit 62 further includes a radio frequency cable 7 connecting across two circuit boards. A first end of the radio frequency cable 7 is configured to be connected to a second end of the first capacitance limitation module 22 for the second antenna and a second end of the signal isolation module 42 for the second antenna respectively. The second end of the radio frequency cable 7 is configured to be connected to the second detection port 112.

The first capacitance limitation module 22 for the second antenna includes a capacitor C6, a capacitor C7, an inducer L6, and an inducer L7. A first end of the capacitor C6 is taken as a first end of the first capacitance limitation module 22 for the second antenna and is connected to the second antenna 52. A second end of the capacitor C6 is respectively connected to a first end of the inducer L6 and a first end of the second antenna matching circuit 82. A second end of the inducer L6 is grounded. A first end of the capacitor C7 is connected to a second end of the second antenna matching circuit 82 and a first end of the inducer L7 respectively. A second end of the inducer L7 is grounded. A second end of the capacitor C7 is taken as a second end of the first capacitance limitation module 22 for the second antenna and is connected to the first end of the radio frequency cable 7. The second end of the radio frequency cable 7 is connected to the second detection port 112.

The second capacitance limitation module 32 for the second antenna includes a capacitor C8 and an inducer L8. A first end of the capacitor C8 is taken as a first end of the second capacitance limitation module 32 for the second antenna and is connected to the second detection port 112. A second end of the capacitor C8 is taken as a second end of the second capacitance limitation module 32 for the second antenna and is connected to the second power control circuit 62. A first end of the inducer L8 is connected to the first end of the capacitor C8, and a second end of the inducer L8 is grounded.

The signal isolation module 42 for the second antenna includes an inducer L9 and an inducer L10. A first end of the inducer L9 is taken as a first end of the signal isolation module 42 for the second antenna and is connected to the second antenna 52. A second end of the inducer L9 is connected to a first end of the inducer L10. A second end of the inducer L10 is taken as a second end of the signal isolation module 42 for the second antenna and is connected to the first end of the radio frequency cable 7. The second end of the radio frequency cable 7 is connected to the second detection port 112. The signal isolation module 42 for the second antenna is configured to isolate radio frequency signals on the radio frequency path between the second antenna 52 and the second power control circuit 62 and to transmit SAR signals of the second antenna 52.

The mobile terminal obtains SAR signals of the first antenna through the first detection channel of the SAR sensor, obtains SAR signals of the second antenna through the second detection channel of the SAR sensor, determines whether a distance between the human body and the first antenna is smaller than or equal to a safe threshold according to the SAR signals of the first antenna, and determines whether a distance between the human body and the second antenna is smaller than or equal to the safe threshold according to the SAR signals of the second antenna. When the distance between the human body and the first antenna is smaller than or equal to the safe threshold, the transmission power of the first antenna is reduced. When the distance between the human body and the second antenna is smaller than or equal to the safe threshold, the transmission power of the second antenna is reduced.

In the above example, the mobile terminal transmits SAR signals of the antenna (main antenna) distant from the detection port of the SAR sensor through a radio frequency cable available between the main board and the sub-board. In this way, in a case where the cost of SAR devices or area for distribution of the devices is not increased, one SAR sensor chip may synchronously detect SAR signals of an antenna (WiFi antenna) close to the SAR sensor and SAR signals of an antenna (main antenna) far away from the SAR sensor. With one SAR sensor synchronously detecting the SAR signals of two antennas, the mobile terminal separately processes the SAR signals of each antenna, and control of reducing SARs of each antenna independently may be achieved. Therefore, a solution for reducing SAR is more flexible, and the hardware cost thereof is reduced.

What is claimed is:

1. A device for detecting specific absorption rate (SAR), comprising: an SAR sensor, a plurality of first capacitance limitation modules, a plurality of second capacitance limitation modules and a plurality of signal isolation modules; wherein,
the SAR sensor comprises a plurality of detection ports, and each of the plurality of detection ports is configured to perform SAR detection on one of a plurality of antennas;
for each of the plurality of first capacitance limitation modules, a first end of the first capacitance limitation module is connected to a respective antenna of the plurality of antennas, a second end of the first capacitance limitation module is connected to a respective detection port of the plurality of detection ports, and the first capacitance limitation module is configured to limit a capacitance value on a side of the respective antenna connected to the first capacitance limitation module;
for each of the plurality of second capacitance limitation modules, a first end of the second capacitance limitation module is connected to a respective detection port of the plurality of detection ports, a second end of the second capacitance limitation module is connected to a respective power control circuit of a plurality of power control circuits, and the second capacitance limitation module is configured to limit a capacitance value on a side of the respective power control circuit connected to the second capacitance limitation module;
for each of the plurality of signal isolation modules, a first end of the signal isolation module is connected to a respective antenna of the plurality of antennas, a second end of the signal isolation module is connected to a respective detection port of the plurality of detection ports, and the signal isolation module is configured to isolate a radio frequency signal on a radio frequency path between the respective antenna connected to the signal isolation module and a respective power control circuit connected to the signal isolation module and to transmit an SAR signal of the respective antenna connected to the signal isolation module; and
in response to the SAR sensor, the plurality of power control circuits, the plurality of second capacitance limitation modules, a portion of the plurality of antennas and first capacitance limitation modules and signal isolation modules corresponding to the portion of the plurality of antennas being on a first circuit board, and another portion of the plurality of antennas and first capacitance limitation modules and signal isolation modules corresponding to the another portion of the plurality of antennas being on a second circuit board which is different from the first circuit board, for each of the another portion of the plurality of antennas, the radio frequency path between the antenna and the respective power control circuit connected to the antenna comprises a radio frequency cable connecting across the first circuit board and the second circuit board; a first end of the radio frequency cable is connected to a second end of one of the plurality of first capacitance limitation modules and a second end of one of the plurality of signal isolation modules and a second end of the radio frequency cable is connected to one of the plurality of detection ports.

2. The device according to claim 1, wherein,
the radio frequency path comprises an antenna matching circuit configured to perform impedance matching on the respective antenna;
each of the plurality of first capacitance limitation modules comprises: a first capacitor C1, a second capacitor C2, a first inducer L1 and a second inducer L2; a first end of the first capacitor C1 in each first capacitance limitation module is taken as the first end of the first capacitance limitation module, a second end of the first capacitor C1 is connected to a first end of the first inducer L1 and a first end of the antenna matching circuit respectively, and a second end of the first inducer L1 is grounded; a first end of the second capacitor C2 is connected to a second end of the antenna matching circuit and a first end of the second inducer L2 respectively, and a second end of the second inducer L2 is grounded; and a second end of the second capacitor C2 is taken as a second end of the first capacitance limitation module.

3. The device according to claim 1, wherein,
each of the plurality of second capacitance limitation modules comprises a third capacitor C3 and a third inducer L3; a first end of the third capacitor C3 is taken as a first end of the second capacitance limitation module, a second end of the third capacitor C3 is taken as a second end of the second capacitance limitation module; and a first end of the third inducer L3 is connected to the first end of the third capacitor C3, and a second end of the third inducer L3 is grounded.

4. The device according to claim 1, wherein,
each of the plurality of signal isolation modules comprises a fourth inducer L4 and a fifth inducer L5; a first end of the fourth inducer L4 is taken as the first end of the signal isolation module, a second end of the fourth inducer L4 is connected to a first end of the fifth inducer L5, and a second end of the fifth inducer L5 is taken as a second end of the signal isolation module.

5. The device according to claim 1, wherein,
the first circuit board is a main board, and the second circuit board is a sub-board; or the first circuit board is the sub-board, and the second circuit board is the main board.

6. A mobile terminal, comprising: a first circuit board, a second circuit board, a plurality of radio frequency cables connecting across the first circuit board and the second circuit board, a plurality of antennas, a plurality of power control circuits and a device for detecting specific absorption rate (SAR); wherein the device for detecting the SAR comprises: an SAR sensor, a plurality of first capacitance limitation modules, a plurality of second capacitance limitation modules, and a plurality of signal isolation modules; wherein,
the SAR sensor comprises a plurality of detection ports, and each of the plurality of detection ports is configured to perform SAR detection on one of the plurality of antennas;
for each of the plurality of first capacitance limitation modules, a first end of the first capacitance limitation module is connected to a respective antenna of the plurality of antennas, a second end of the first capacitance limitation module is connected to a respective detection port of the plurality of detection ports, and the first capacitance limitation module is configured to limit a capacitance value on a side of the respective antenna connected to the first capacitance limitation module;
for each of the plurality of second capacitance limitation modules, a first end of the second capacitance limitation module is connected to a respective detection port of the plurality of detection ports, a second end of the second capacitance limitation module is connected to a respective power control circuit of the plurality of power control circuits, and the second capacitance limitation module is configured to limit a capacitance value on a side of the respective power control circuit connected to the second capacitance limitation module;
for each of the plurality of signal isolation modules, a first end of the signal isolation module is connected to a respective antenna of the plurality of antennas, a second end of the signal isolation module is connected to a respective detection port of the plurality of detection ports, and the signal isolation module is configured to isolate a radio frequency signal on a radio frequency path between the respective antenna connected to the signal isolation module and a respective power control circuit connected to the signal isolation module and to transmit an SAR signal of the respective antenna connected to the signal isolation module; and
in response to the SAR sensor, the plurality of power control circuits, the plurality of second capacitance limitation modules, a portion of the plurality of antennas and first capacitance limitation modules and signal isolation modules corresponding to the portion of the plurality of antennas being on the first circuit board, and another portion of the plurality of antennas and first capacitance limitation modules and signal isolation modules corresponding to the another portion of the plurality of antennas being on the second circuit board which is different from the first circuit board, for each of the another portion of the plurality of antennas, the radio frequency path between the antenna and the respective power control circuit connected to the antenna comprises a radio frequency cable of the plurality of radio frequency cables; a first end of the radio frequency cable is connected to a second end of one of the plurality of first capacitance limitation modules and a second end of one of the plurality of signal isolation modules and a second end of the radio frequency cable is connected to one of the plurality of detection ports.

7. The mobile terminal according to claim 6, wherein,
the radio frequency path comprises an antenna matching circuit configured to perform impedance matching on the respective antenna;
each of the plurality of first capacitance limitation modules comprises: a first capacitor C1, a second capacitor C2, a first inducer L1 and a second inducer L2; a first end of the first capacitor C1 in each first capacitance limitation module is taken as the first end of the first capacitance limitation module, a second end of the first capacitor C1 is connected to a first end of the first inducer L1 and a first end of the antenna matching circuit respectively, and a second end of the first inducer L1 is grounded; a first end of the second capacitor C2 is connected to a second end of the antenna matching circuit and a first end of the second inducer L2 respectively, and a second end of the second inducer L2 is grounded; and a second end of the second capacitor C2 is taken as a second end of the first capacitance limitation module.

8. The mobile terminal according to claim 6, wherein,
each of the plurality of second capacitance limitation modules comprises a third capacitor C3 and a third inducer L3; a first end of the third capacitor C3 is taken as a first end of the second capacitance limitation module, a second end of the third capacitor C3 is taken as a second end of the second capacitance limitation module; and a first end of the third inducer L3 is connected to the first end of the third capacitor C3, and a second end of the third inducer L3 is grounded.

9. The mobile terminal according to claim 6, wherein,
each of the plurality of signal isolation modules comprises a fourth inducer L4 and a fifth inducer L5; a first end of the fourth inducer L4 is taken as the first end of the signal isolation module, a second end of the fourth inducer L4 is connected to a first end of the fifth inducer L5, and a second end of the fifth inducer L5 is taken as a second end of the signal isolation module.

10. The mobile terminal according to claim 6, wherein, the first circuit board is a main board, and the second circuit board is a sub-board; or the first circuit board is the sub-board, and the second circuit board is the main board.
